(19) United States
(12) Patent Application Publication
(10) Pub. No.: US 2025/0248068 A1
(43) Pub. Date: Jul. 31, 2025

(54) SEMICONDUCTOR DEVICE AND METHOD

(71) Applicant: Taiwan Semiconductor Manufacturing Co., Ltd., Hsinchu (TW)

(72) Inventors: De-Wei Yu, Ping-Tung (TW); Hsueh-Chang Sung, Zhubei City (TW); Ming-Feng Hsieh, New Taipei City (TW)

(21) Appl. No.: 18/428,315

(22) Filed: Jan. 31, 2024

(51) Int. Cl. H01L 29/423; H01L 29/06; H01L 29/66; H01L 29/775

(52) U.S. Cl. CPC H10D 30/6735; H10D 30/014; H10D 30/43; H10D 62/121; H10D 64/017

(57) ABSTRACT

A semiconductor device and the method of forming the same are provided. The semiconductor device may include a substrate, a first channel region and a second channel region over the substrate, a gate structure on one or more sidewalls of the first channel region and on one or more sidewalls of the second channel region, and a dielectric spacer on a first side and a second side of the gate structure in a top-down view. The first side opposes the second side. A first portion of the dielectric spacer may extend between the first channel region and the second channel region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 6D, 7A, 7B, 7C, 7D, 8A, 8B, 8C, 9A, 9B, 9C, 10A, 10B, 10C, 11A, 11B, 11C, 11D, 12A, 12B, 12C, 12D, 12E, 13A, 13B, 13C, 14A, 14B, 14C, 15A, 15B, 15C, 16A, 16B, 16C, 17A, 17B, 17C, 17D, 18A, 18B, 18C, 19A, 19B, 19C, 20A, 20B, 20C, 20D, and 21 are views of intermediate stages in the manufacturing of semiconductor devices, such as nano-FETs, in accordance with some embodiments.

FIGS. 22 and 23 illustrate cross-sectional views of fin field-effect transistors (fin-FETs), in accordance with some embodiments.

FIGS. 24A, 24B, 24C, 24D, 25A, 25B, 25C, 25D, 26A, 26B, 26C, 26D, and 27 are views of intermediate stages in the manufacturing of semiconductor devices, such as nano-FETs, in accordance with some embodiments.

FIGS. 28 and 29 illustrate cross-sectional views of fin-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and methods of forming the same. For example, some embodiments provide nano-FETs and fin-FETs, during the manufacturing of which an appropriate material for forming dummy gates may be selected. As a result, an improved control of the channel regions by the gate electrodes may be achieved in the nano-FETs and fin-FETs, thereby improving the performance of the nano-FETs and fin-FETs.

Some embodiments discussed herein are described in the context of a semiconductor device including nano-FETs. However, various embodiments may be applied to dies including other types of transistors (e.g., fin field effect transistors (fin-FETs), vertical field-effect transistors (VFETs), complementary field-effect transistors (CFETs), planar transistors, or the like) in lieu of or in combination with the nano-FETs.

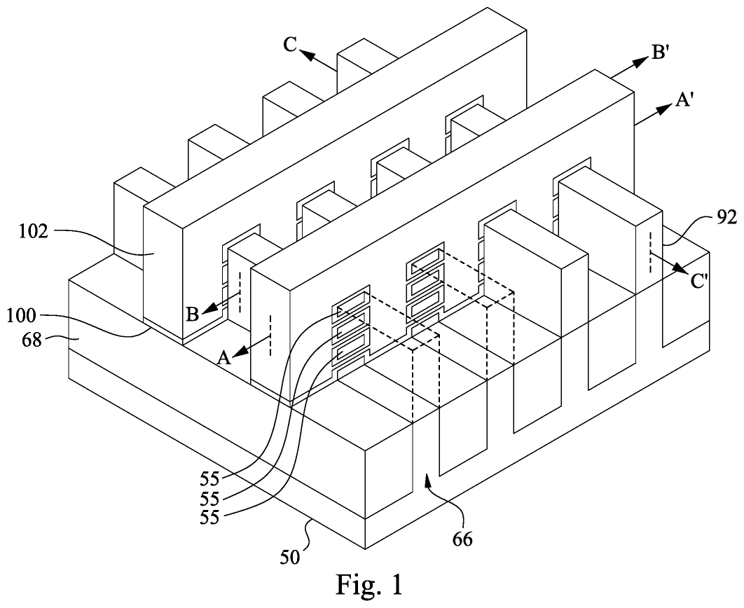

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to the reference cross-section A-A′ and extends through epitaxial source/drain regions 92 of multiple nano-FETs. Reference cross-section C-C′ is perpendicular to the reference cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in fin-FETs.

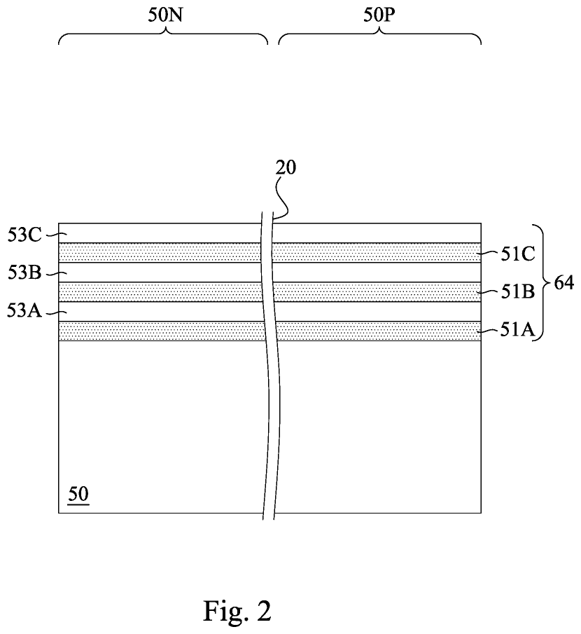

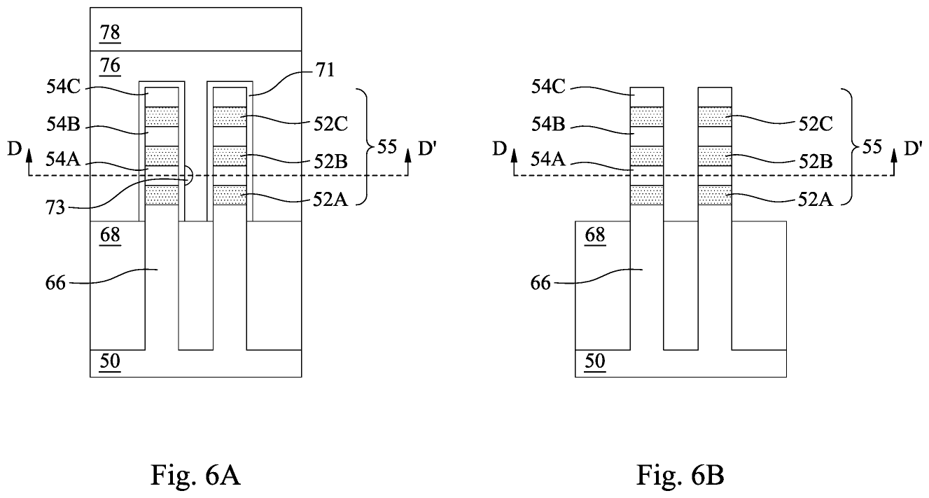

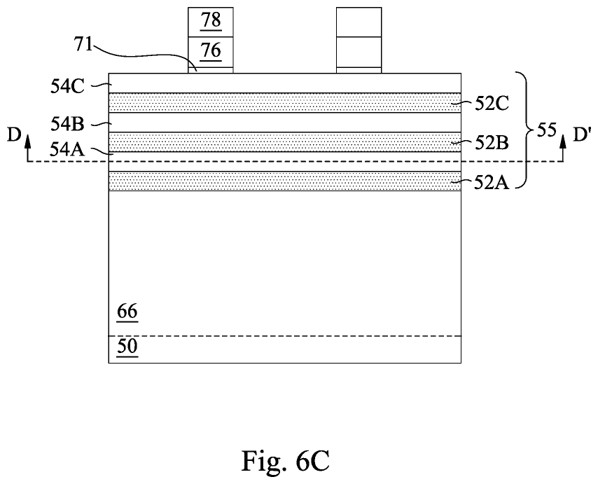

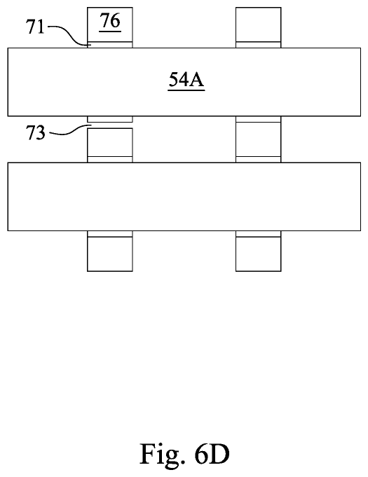

FIGS. 2 through 21 are views of intermediate stages in the manufacturing of semiconductor devices, such as nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, 20A, and 21 illustrate cross-sectional views along the reference cross-section A-A′ illustrated in FIG. 1. FIGS. 6B, 7B, 8B, 9B, 10B, 11B, 12B, 12D, 13B, 14B, 15B, 16B, 17B, 18B, 19B, and 20B illustrate cross-sectional views along the reference cross-section B-B′ illustrated in FIG. 1. FIGS. 6C, 7C, 8C, 9C, 10C, 11C, 11D, 12C, 12E, 13C, 14C, 15C, 16C, 17C, 18C, 19C, and 20C illustrate cross-sectional views along the reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

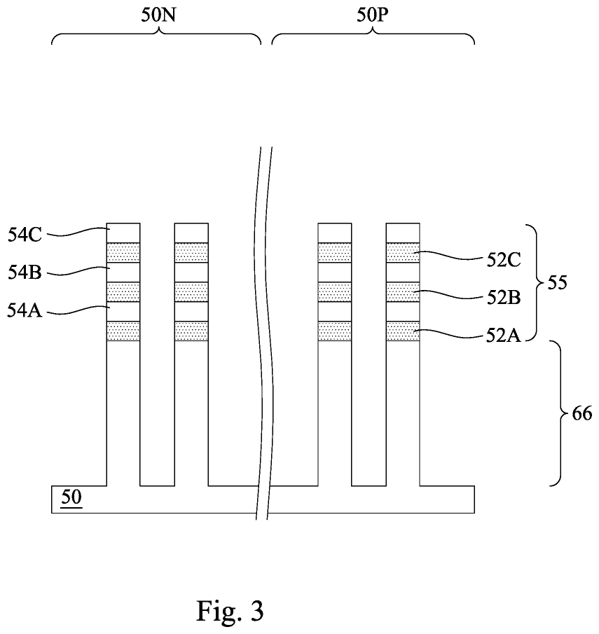

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

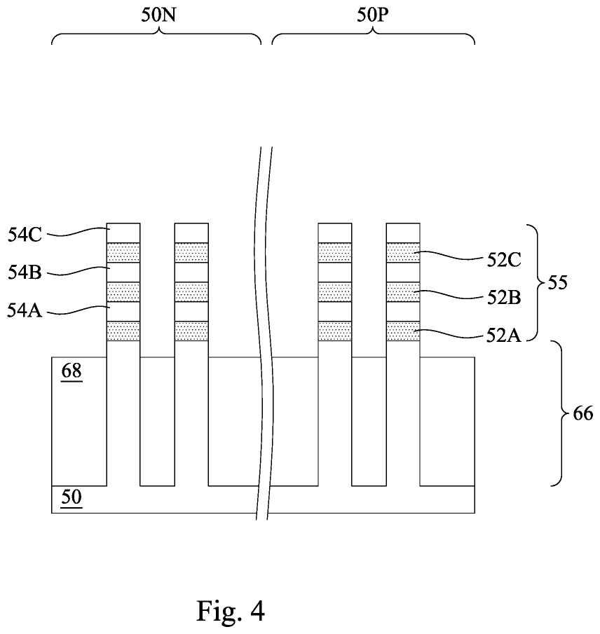

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid may be used.

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

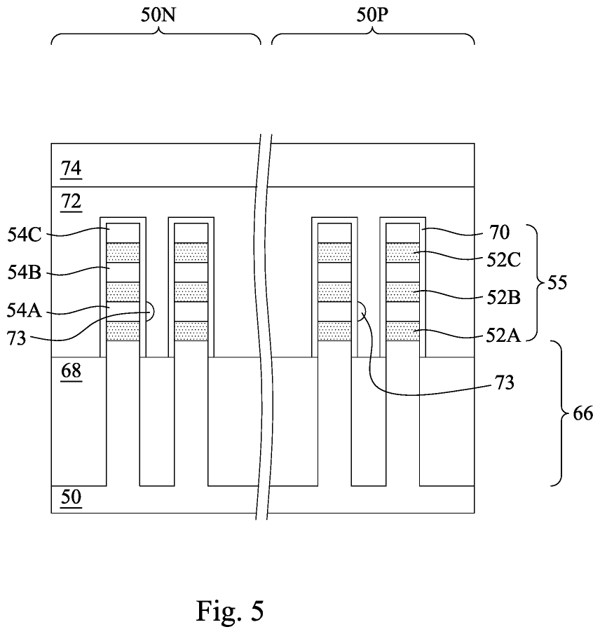

In FIG. 5, a dummy dielectric layer 70 is formed on the fins 66 and/or the nanostructures 55, a dummy gate layer 72 is formed over the dummy dielectric layer 70, and a mask layer 74 is formed over the dummy gate layer 72. The dummy dielectric layer 70 may be, for example, silicon oxide, silicon nitride, a combination thereof, or the like, and may be deposited or thermally grown using suitable processes. The dummy dielectric layer 70 is shown in FIG. 5 covering the fins 66 and the nanostructures 55 for illustrative purposes. In some embodiments, the dummy dielectric layer 70 may be deposited such that the dummy dielectric layer 70 also covers the STI regions 68 and extends between the dummy gate layer 72 and the STI regions 68.

The dummy gate layer 72 may be deposited over the dummy dielectric layer 70 and then planarized, such as by a CMP. The dummy gate layer 72 may be formed of materials with a high etching selectivity to the materials of the STI regions 68. The dummy gate layer 72 may be formed of polycrystalline silicon (polysilicon) or the like. The dummy gate layer 72 may be deposited by a suitable deposition process, such as physical vapor deposition (PVD), CVD, sputter deposition, or the like. The deposition temperature may be in range from about 500° C. to about 700° C., and the deposition pressure may be in range from about 0.1 torr to about 0.5 torr.

Voids 73 may be disposed in the dummy gate layer 72 after the dummy gate layer 72 is formed. FIG. 5 shows one void 73 disposed in the n-type region 50N and one void 73 disposed in the p-type region 50P for illustrative purposes. The n-type region 50N and/or the p-type region 50P may each have more than one void 73. FIG. 5 shows the vertical locations of the voids 73 to be adjacent the second nanostructures 54A for illustrative purposes. The vertical locations of the voids 73 may be anywhere in the dummy gate layer 72, including the being adjacent other nanostructures in the nanostructures 55 and/or top portions of the fins 66. FIG. 5 shows the horizontal locations of the voids 73 to be between the two stacks of the nanostructures 55 for illustrative purposes. The horizontal locations of the voids 73 may be anywhere in the dummy gate layer 72 including being to the left and/or right of the two stacks of the nanostructures 55. FIG. 5 shows the voids 73 having shapes of a half-oval for illustrative purposes. The voids 73 may have any shapes (e.g., half-circle).

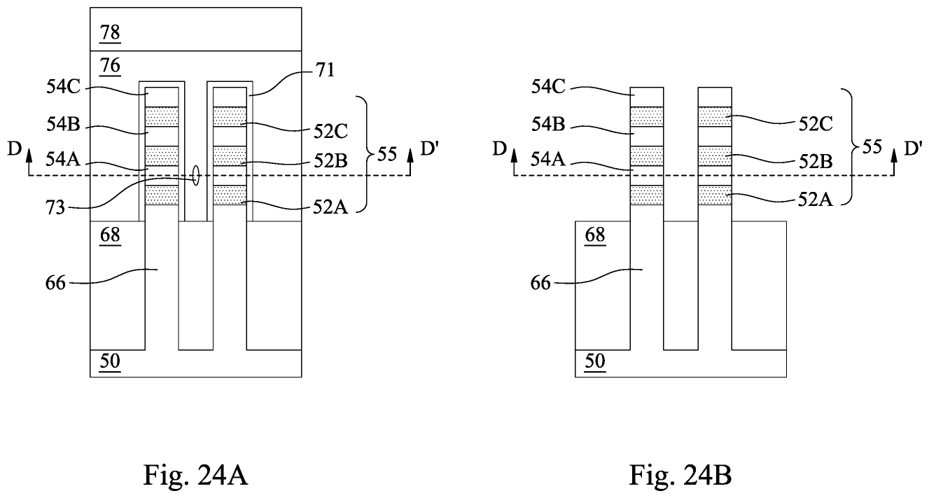

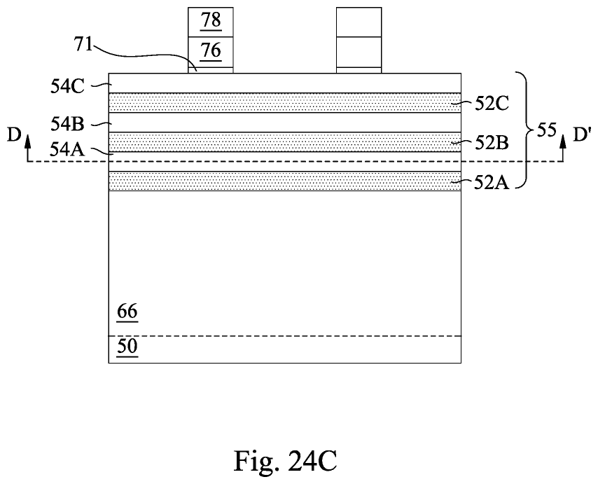

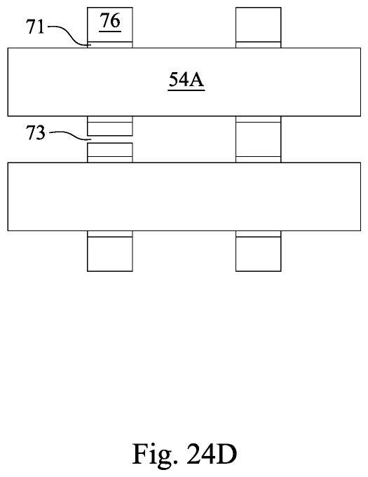

In some embodiments, the voids 73 are in contact with the dummy dielectric layer 70, which leaves the dummy dielectric layer 70 partially covered by the dummy gate layer 72 and partially exposed. Such embodiments may correspond to the embodiments in which polycrystalline silicon is used to form the dummy gate layer 72, and are used as examples in the description of FIGS. 5 through 21. In some embodiments, the voids 73 are encircled by the dummy gate layer 72, which may leave the dummy dielectric layer 70 fully covered by the dummy gate layer 72. Such embodiments may correspond to the embodiments in which amorphous silicon is used to form the dummy gate layer 72, and are described in greater details later with respect to FIGS. 24A through 27. The voids 73 may be at least partially filled during a subsequent process. The mask layer 74 may be deposited over the dummy gate layer 72. The mask layer 74 may include, silicon nitride, silicon oxynitride, or the like. In some embodiments, a single dummy gate layer 72 and a single mask layer 74 are formed across the n-type region 50N and the p-type region 50P.

FIGS. 6A through 21 illustrate various additional steps in the manufacturing of the nano-FET devices, in accordance to some embodiments. FIGS. 6A through 21 illustrate features in either and/or both the n-type region 50N or the p-type region 50P. In FIGS. 6A through 6D, masks 78, dummy gates 76, and dummy gate dielectrics 71 are formed. FIG. 6D illustrates a top-down view of the structure illustrated in FIGS. 6A, 6B, and 6C, including the second nanostructure 54A, along the reference cross-sections D-D′. The dummy gates 76 and dummy gate dielectrics 71 may be collectively referred to as dummy gate structures.

The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. The void 73 may be in contact with and may extend along a portion of the dummy gate dielectrics 71, which leaves the portion of the dummy gate dielectrics 71 exposed. The void 73 may extend through the corresponding dummy gate 76. The etching processes used to form the dummy gates 76 may enlarge the void 73.

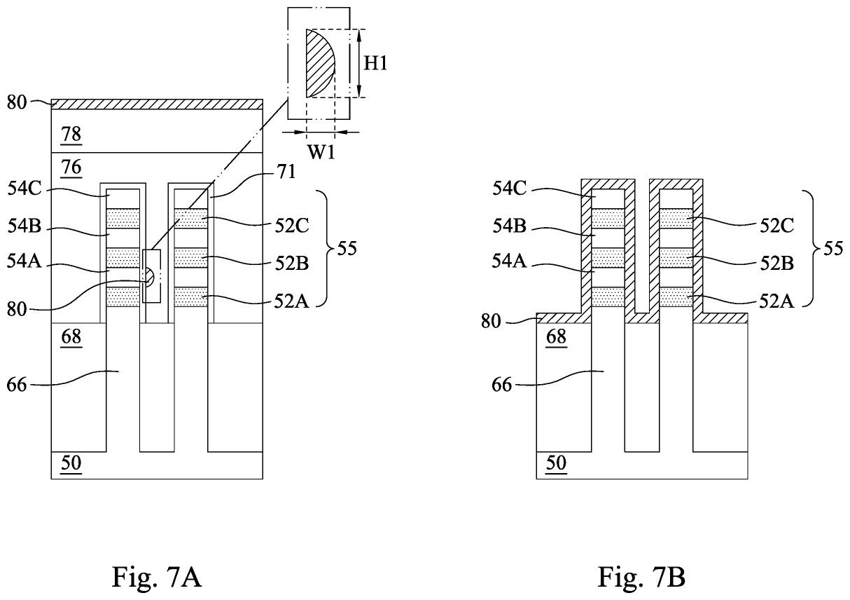

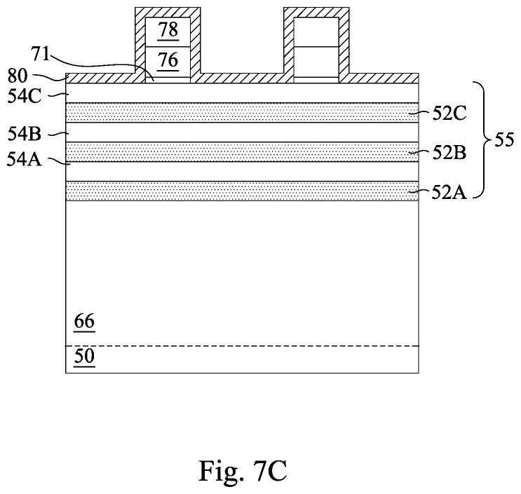

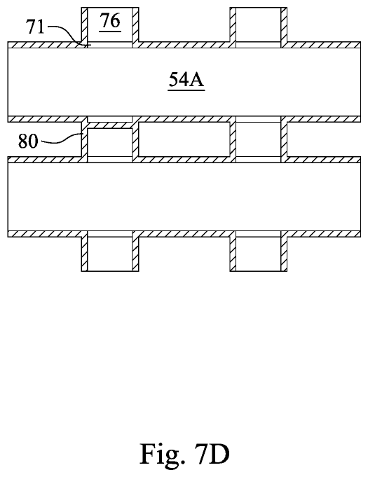

In FIGS. 7A through 7D, a spacer layer 80 is formed. FIG. 7D illustrates a top-down view of the structure illustrated in FIGS. 7A, 7B, and 7C, including the second nanostructure 54A, along the reference cross-sections D-D′. The spacer layer 80 may be formed on top surfaces of the STI regions 68; on top surfaces and sidewalls of the nanostructures 55 and the masks 78; and on sidewalls of the fins 66, the dummy gates 76, and the dummy gate dielectrics 71. The spacer layer 80 may also at least partially fill the void 73 in the dummy gates 76. As shown in FIG. 7D, a first portion and a second portion of the spacer layer 80 may extend on opposing sides of the dummy gate 76, and a third portion of the spacer layer 80 may extend through the dummy gate 76 and connect to the first portion and the second portion of the spacer layer 80. The first portion, the second portion, and the third portion of the spacer layer 80 may form a shape of an “H” in the top-down view.

The spacer layer 80 may be a single layer of one material or multiple sub-layers of different materials with different etch rates. In some embodiments, the spacer layer 80 comprise two sub-layers with different materials of different etch rates. The material(s) of the spacer layer 80 may be selected from dielectric materials such as, silicon oxide, silicon nitride, silicon oxynitride, or the like. The spacer layer 80 may be formed by a suitable thermal oxidation process or a suitable deposition process, such as CVD, ALD, or the like. As shown in FIG. 7A, in some embodiments, the third portion of the spacer layer 80, which fills in the void 73, may be in the shape of a half-oval with a height H1 in a range from about 1 nm to about 30 nm and a width W1 in a range from about 1 nm to about 30 nm.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1×10¹⁵ atoms/cm³ to about 1×10¹⁹ atoms/cm³. An annealing may be used to repair implant damage and to activate the implanted impurities.

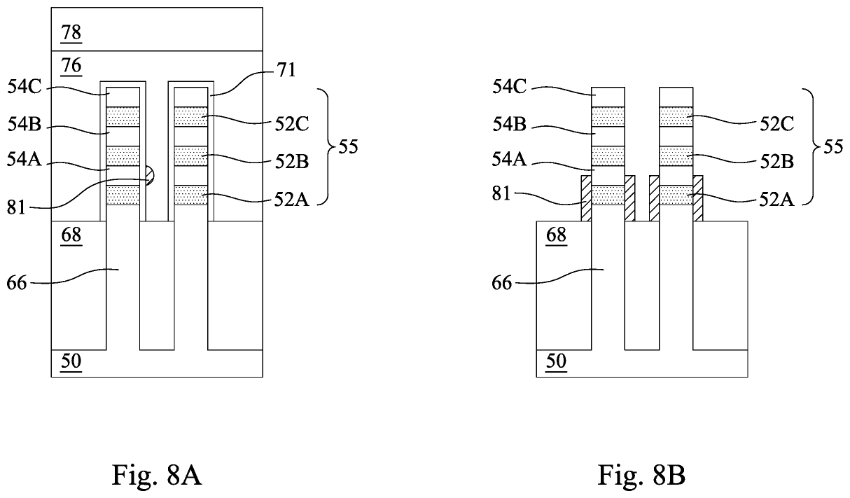

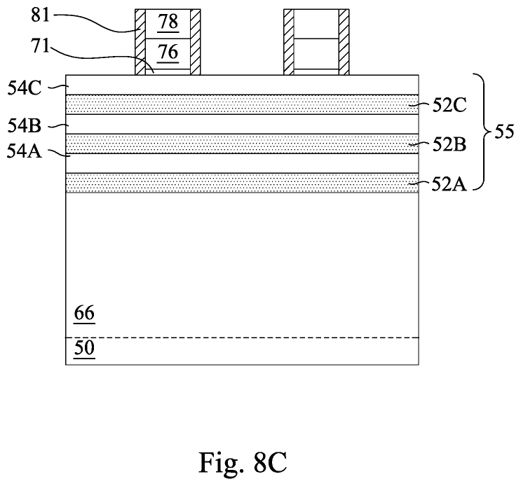

In FIGS. 8A through 8C, the spacer layer 80 is patterned to form first spacers 81. The spacers 81 may self-align subsequently formed source drain regions, as well as protect the dummy gate dielectrics 71 and the dummy gate 76 during subsequent etching processes. The spacer layer 80 may be patterned by one or more suitable etching processes, such as isotropic etching processes (e.g., a wet etching processes), anisotropic etching process (e.g., a dry etching processes), or the like. After the one or more etching processes, the spacers 81 may remain on sidewalls of the fins 66, the nanostructures 55, the masks 78, the dummy gates 76, and the dummy gate dielectrics 71. The first portion, the second portion, and the third portion of the spacer layer 80, described with respect to FIG. 7D, may remain intact after the one or more etching processes, and may be referred to as the first portion, the second portion, and the third portion of the spacers 81.

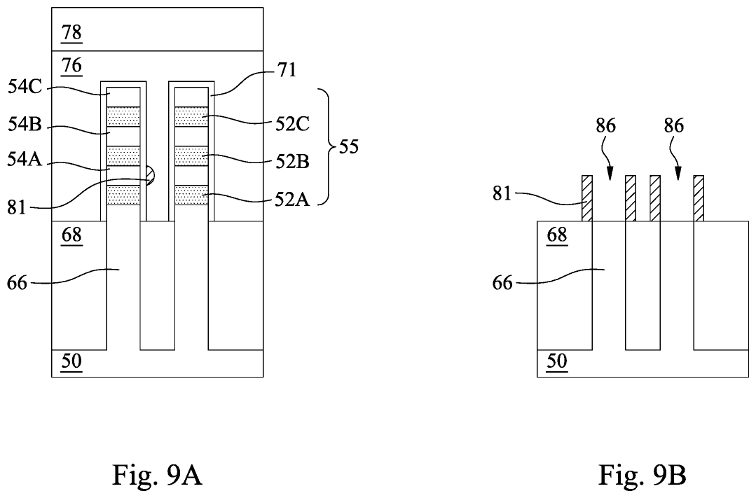

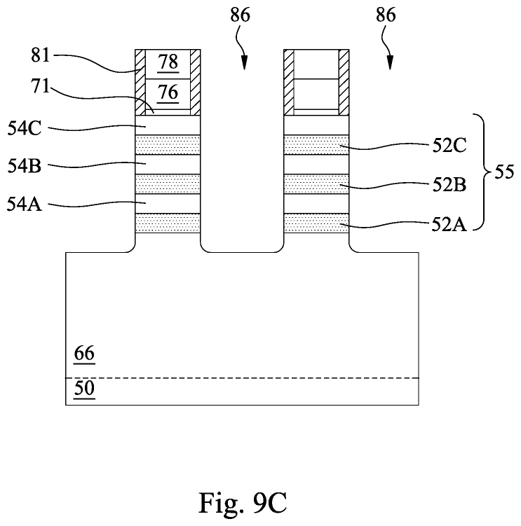

In FIGS. 9A through 9C, recesses 86 are formed in the fins 66, the nanostructures 55, and the substrate 50, in accordance with some embodiments. Epitaxial source/drain regions may be subsequently formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. In some embodiments, the bottom surfaces of the recesses 86 are disposed below the top surfaces of the STI regions 68 or the like.

The recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

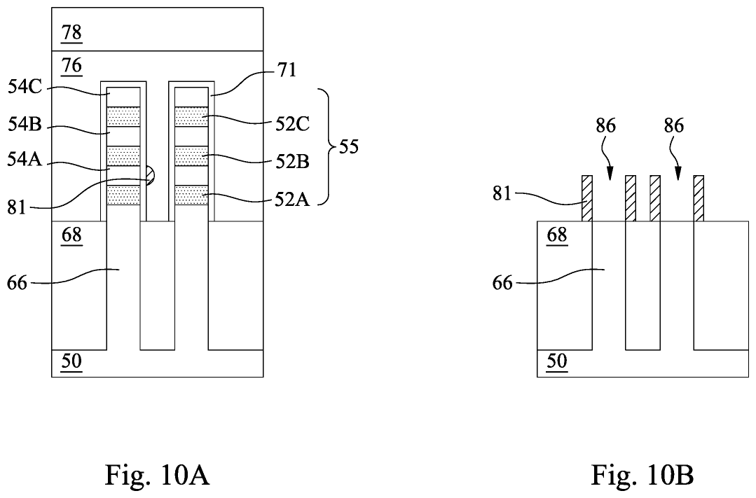

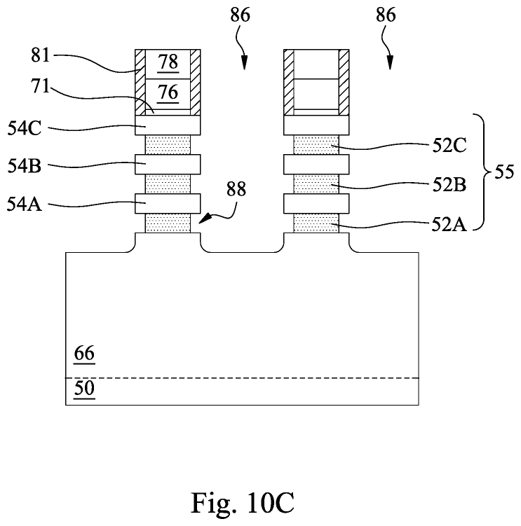

In FIGS. 10A through 10C, portions of sidewalls of the first nanostructures 52 exposed by the recesses 86 are etched to form sidewall recesses 88. Although sidewalls of the first nanostructures 52 adjacent the sidewall recesses 88 are illustrated as being straight in FIG. 10C, the sidewalls may be concave in some embodiments. The sidewalls may be etched using isotropic etching processes, such as wet etching or the like. In the embodiments in which the first nanostructures 52 comprise silicon-germanium or the like, and the second nanostructures 54 comprise silicon, silicon carbide, or the like, tetramethylammonium hydroxide (TMAH), ammonium hydroxide (NH₄OH), or the like may be used to etch sidewalls of the first nanostructures 52.

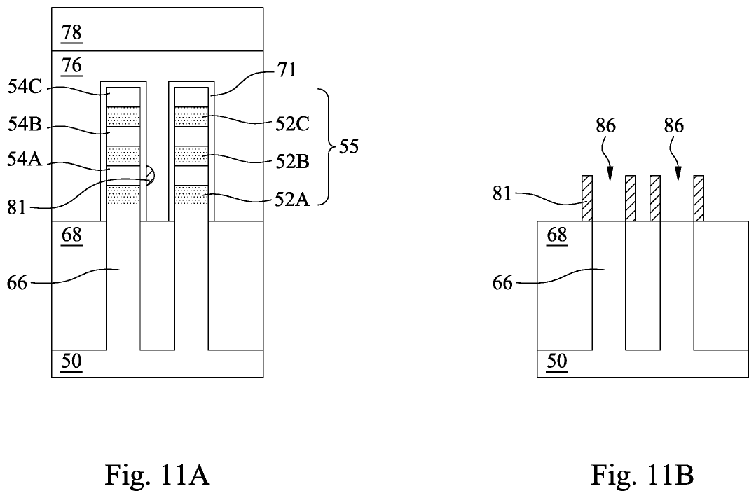

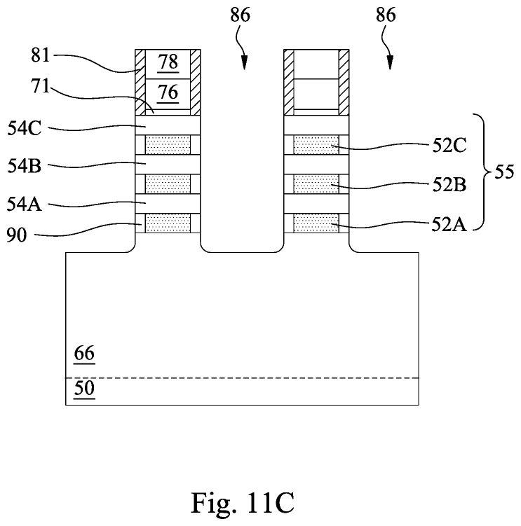

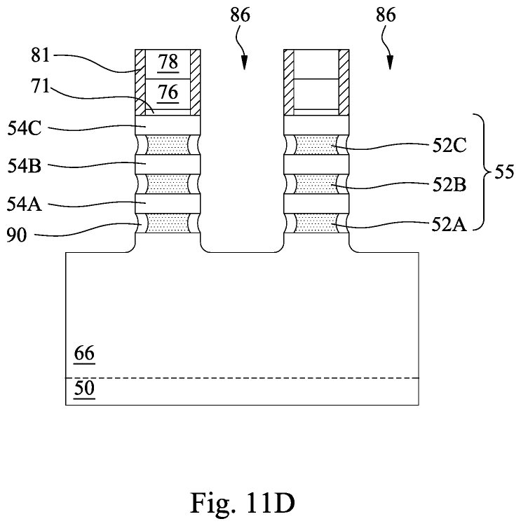

In FIGS. 11A through 11D, first inner spacers 90 are formed in the sidewall recess 88. The first inner spacers 90 may act as isolation features between subsequently formed source/drain regions and a gate structure. As will be discussed in greater detail below, source/drain regions may be formed in the recesses 86, while the first nanostructures 52 may be replaced with corresponding gate structures.

The first inner spacers 90 may be formed by depositing an inner spacer layer (not separately illustrated) over the structures illustrated in FIGS. 10A through 10C, and then etching the inner spacer layer. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be etched to form the first inner spacers 90 by an anisotropic etching process, such as RIE, NBE, or the like. The first inner spacers 90 may be used to protect subsequently formed source/drain regions during subsequent etching processes, such as etching processes used to form gate structures.

Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54. Moreover, although the outer sidewalls of the first inner spacers 90 are illustrated as being straight in FIG. 11C, the outer sidewalls of the first inner spacers 90 may be concave. As an example, FIG. 11D illustrates the embodiments in which sidewalls of the first nanostructures 52 are concave, outer sidewalls of the first inner spacers 90 are concave, and the first inner spacers 90 are recessed from sidewalls of the second nanostructures 54.

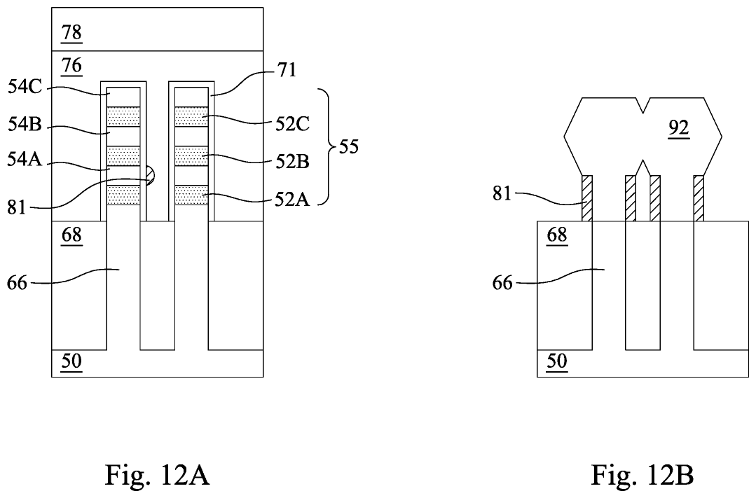

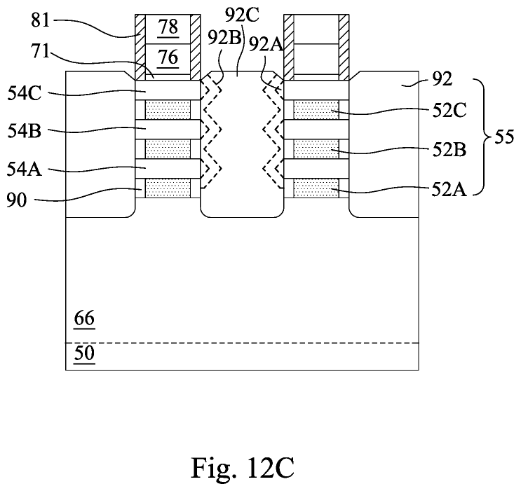

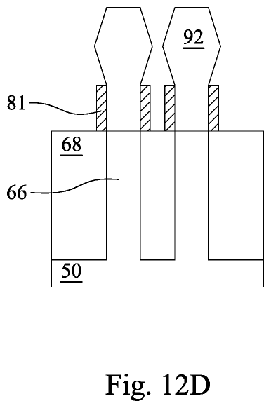

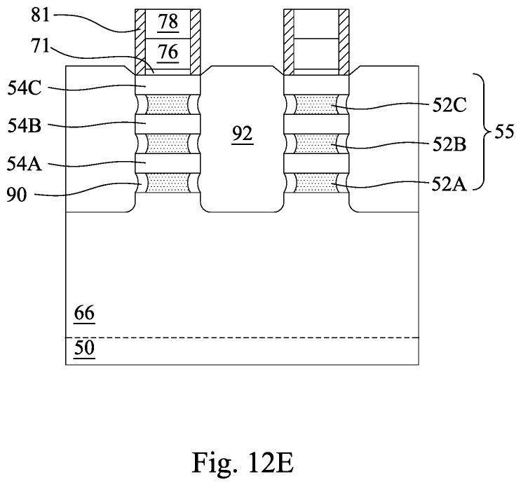

In FIGS. 12A through 12E, epitaxial source/drain regions 92 are formed in the recesses 86. In some embodiments, the epitaxial source/drain regions 92 may exert stress on the second nanostructures 54, thereby improving performance. As illustrated in FIG. 12C, the epitaxial source/drain regions 92 are formed in the recesses 86 such that each dummy gate 76 is disposed between respective neighboring pairs of the epitaxial source/drain regions 92.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the fins 66 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In some embodiments, adjacent epitaxial source/drain regions 92 remain separated after the epitaxy process is completed as illustrated by FIG. 12D. In the embodiments illustrated in FIGS. 12B and 12D, the spacers 81 may be formed on a top surface of the STI regions 68 thereby blocking the epitaxial growth of the epitaxial source/drain regions 92 adjacent the top surface of the STI regions 68. As a result, the spacers 81 may extend on lower sidewalls of the separated lower portions of the epitaxial source/drain regions 92. In some embodiments, the etching process used to form the spacers 81 may be adjusted to remove the spacers 81 on the top surface of the STI regions 68 to allow the epitaxial source/drain regions 92 to extend on the top surface of the STI regions 68.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

FIG. 12E illustrates the embodiments in which sidewalls of the first nanostructures 52 are concave, outer sidewalls of the first inner spacers 90 are concave, and the first inner spacers 90 are recessed from sidewalls of the second nanostructures 54. As illustrated in FIG. 12E, the epitaxial source/drain regions 92 may be formed in contact with the first inner spacers 90 and may extend past sidewalls of the second nanostructures 54.

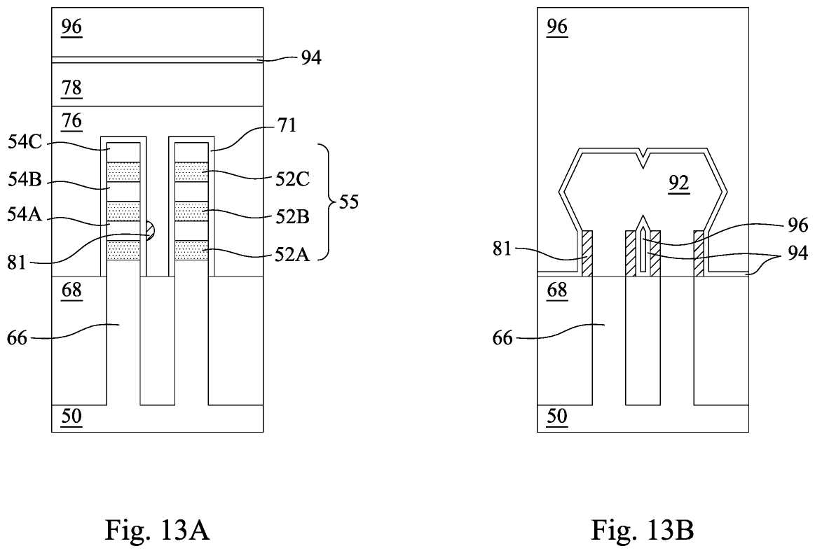

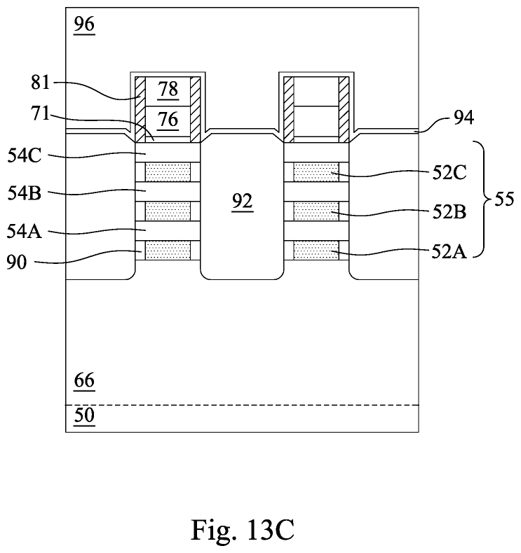

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having a different etch rate than the material of the overlying first ILD 96.

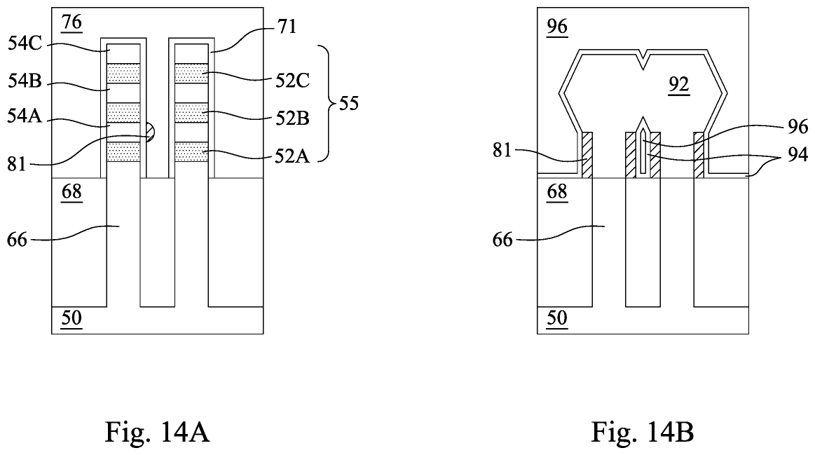

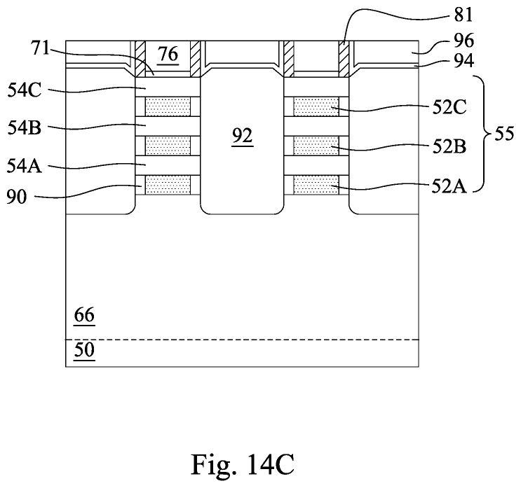

In FIGS. 14A through 14C, a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

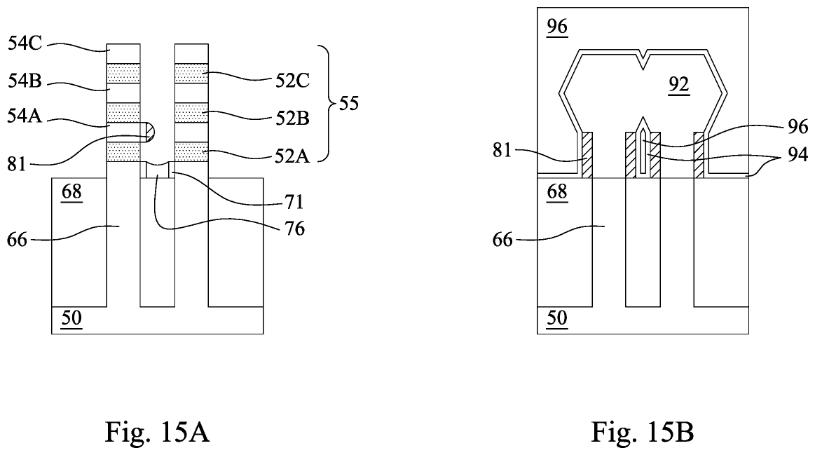

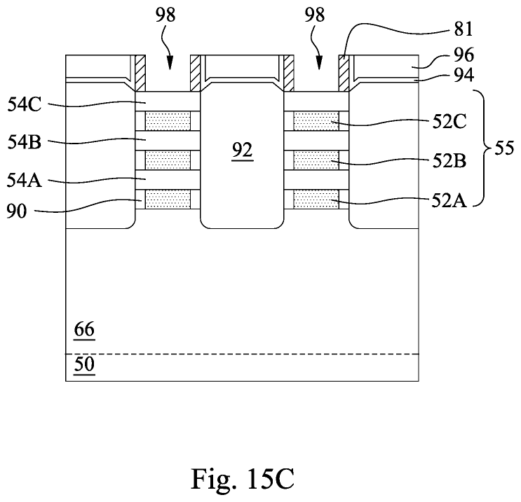

In FIGS. 15A through 15C, the dummy gates 76 and the dummy gate dielectrics 71 are at least partially removed in one or more etching processes to form third recesses 98. In some embodiments, a portion of the dummy gate dielectrics 71 between the nanostructures 55 (e.g., the second nanostructure 54A) and the third portion of the spacers 81 remains intact after the one or more etching processes. In some embodiments, a portion of the dummy gate 76 and portions of the dummy gate dielectrics 71 underneath the third portion of the spacers 81 and on the STI regions 68 remains intact after the one or more etching processes. In some embodiments, the third portion of the spacers 81 is separated from the remaining portion of the dummy gate 76. The dummy gates 76 and the dummy gate dielectrics 71 may be at least partially removed by an anisotropic dry etching process. The dry etching processes may use reaction gas(es) that selectively etch the dummy gates 76 and the dummy gate dielectrics 71 at faster rates than the first ILD 96 and/or the spacers 81. Each of the third recess 98 exposes and/or overlies portions of nanostructures 55, which act as channel regions in subsequently completed nano-FETs. Portions of the nanostructures 55 (e.g., the second nanostructures 54), which may act as the channel regions, are disposed between neighboring pairs of the epitaxial source/drain regions 92. During the etching processes, the dummy gate dielectrics 71 may be used as etch stop layers when the dummy gates 76 are removed and may be removed after the removal of the dummy gates 76.

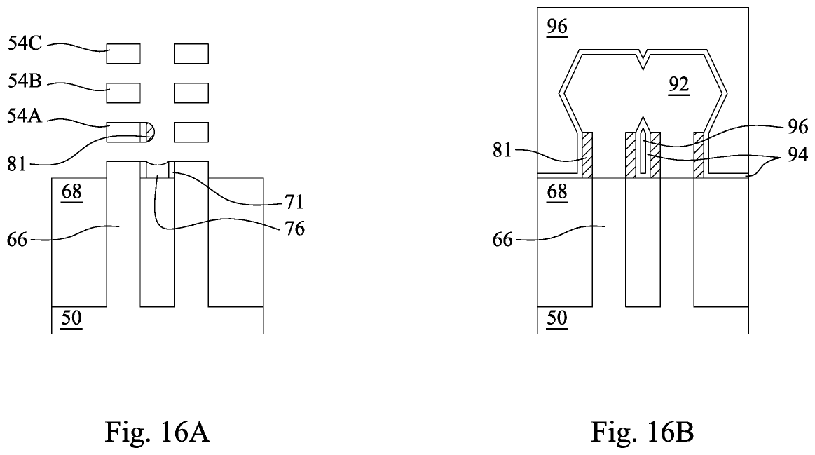

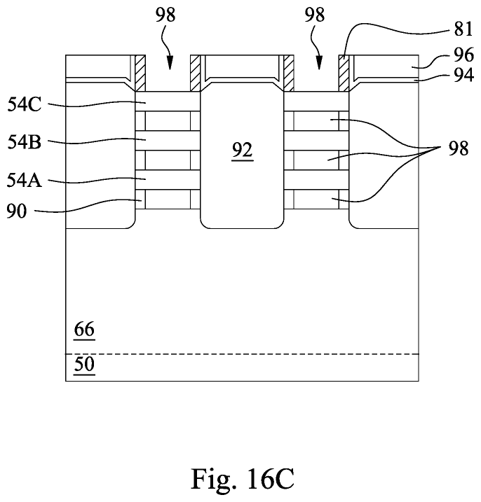

In FIGS. 16A through 16C, the first nanostructures 52 are removed, which extends the third recesses 98. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

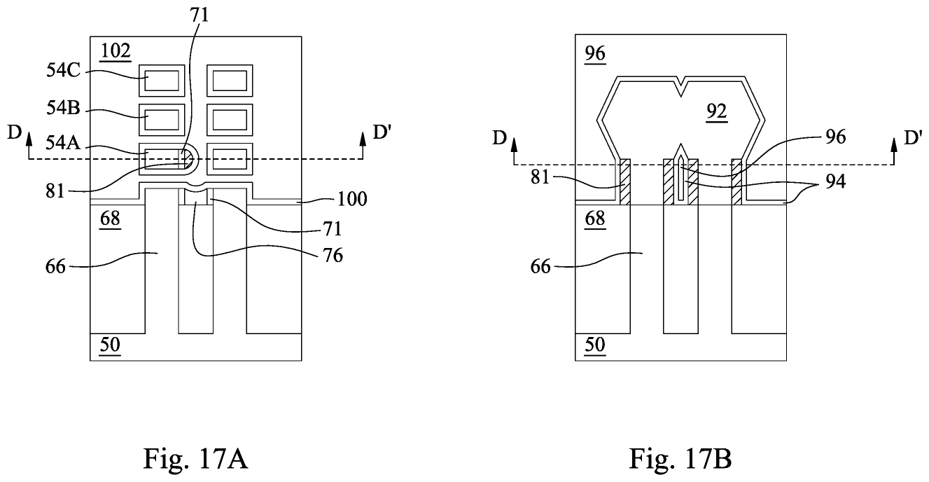

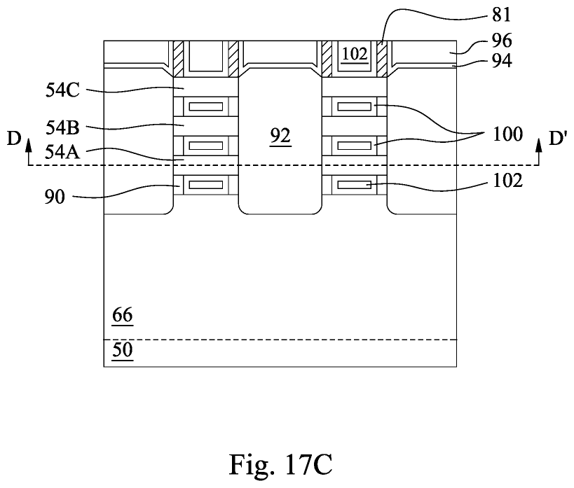

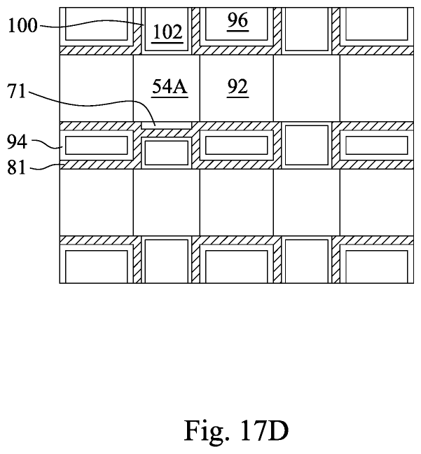

In FIGS. 17A through 17D, gate dielectric layers 100 and gate electrodes 102 are formed in the third recesses 98. FIG. 17D illustrates a top-down view of the structure illustrated in FIGS. 17A, 17B, and 17C, including the second nanostructure 54A, along the reference cross-sections D-D′. The gate dielectric layers 100 may be deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the spacers 81, and the STI regions 68 as well as on sidewalls of the spacers 81 and the first inner spacers 90. Further, gate dielectric layers 100 may be formed on exposed surfaces of the third portion of the spacers 81, and on exposed surfaces of remaining portions of the dummy gate dielectrics 71 and the dummy gates 76.

In some embodiments, the gate dielectric layers 100 comprise one or more dielectric layers, such as an oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include an oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100, respectively, and fill the remaining portions of the third recesses 98. The gate electrodes 102 and the gate dielectric layers 100 and the may wrap around (e.g., encircle) some of the second nanostructures 54 and extend between the second nanostructures 54 and the fins 66. In some embodiments, the gate electrodes 102 and the gate dielectric layers 100 and the may wrap around (e.g., encircle) the second nanostructures 54A, the third portion of the spacers 81, and the remaining portion of the dummy gate dielectric 71 between the second nanostructures 54A and the third portion of the spacers 81. As a result, the second nanostructures 54A, the third portion of the spacers 81, and the remaining portion of the dummy gate dielectric 71 between the second nanostructures 54A and the third portion of the spacers 81 may extend through a same opening in the gate electrodes 102. In some embodiments, the gate electrodes 102 and the gate dielectric layers 100 extend between the third portion of the spacers 81 and the remaining portion of the dummy gates 76.

The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A, 17C, and 17D, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures.

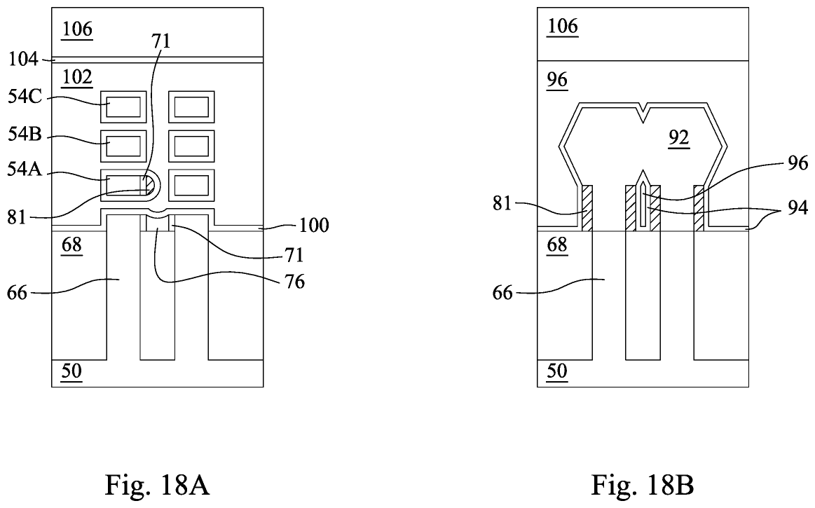

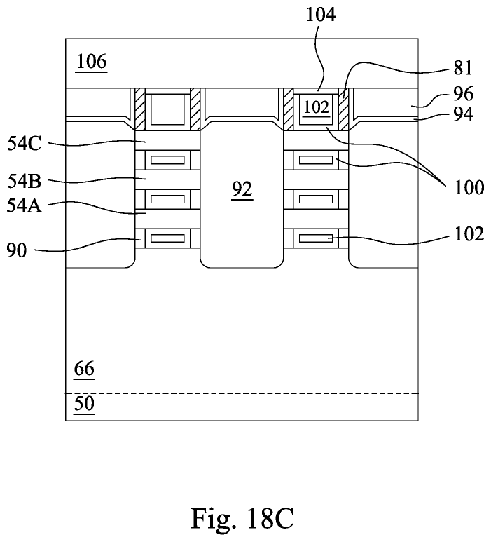

In FIGS. 18A through 18C, the gate structures (including the gate dielectric layers 100 and the corresponding overlying gate electrodes 102) are recessed, and recesses are formed directly over the gate structures and between opposing portions of spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts may extend through the gate masks 104 to contact the top surfaces of the recessed gate electrodes 102. As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

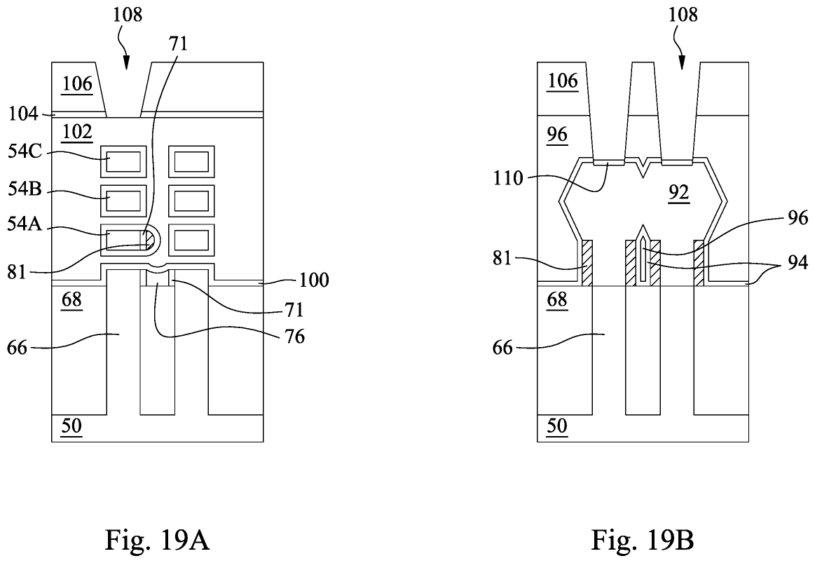

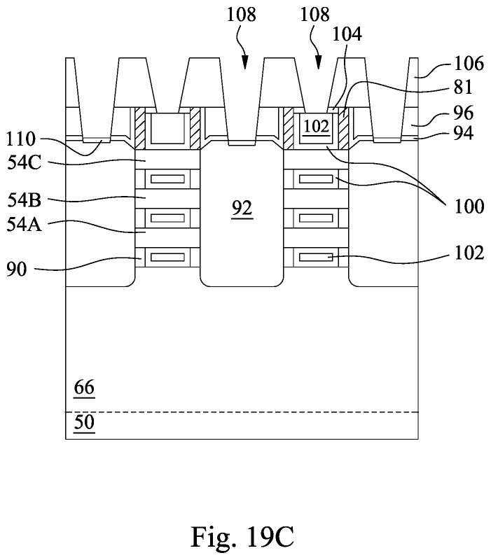

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a first thermal annealing process to form the first silicide regions 110. In some embodiments, the first thermal annealing process is performed at a temperate of about 450° C. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

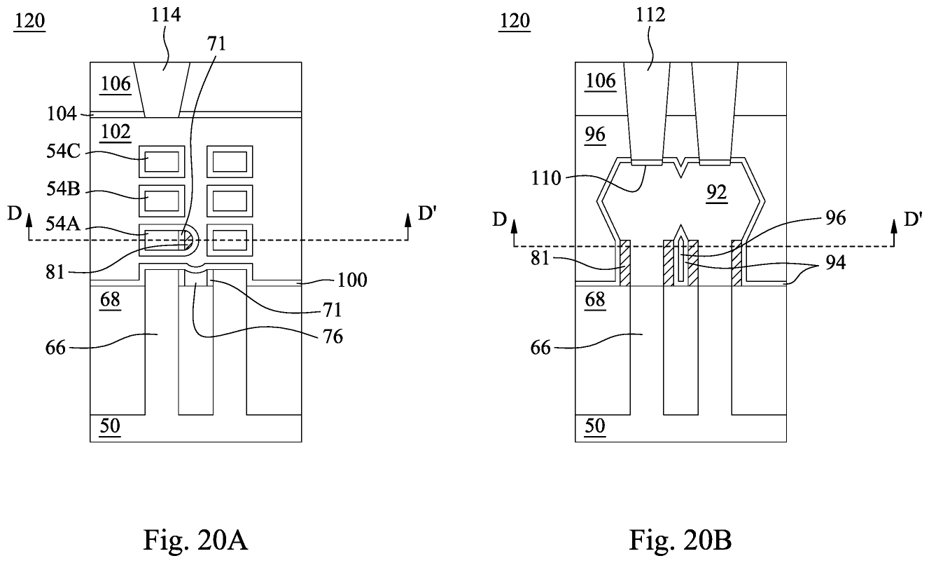

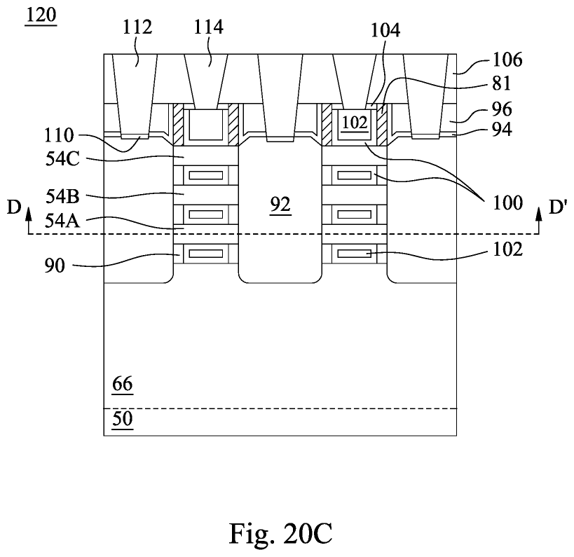

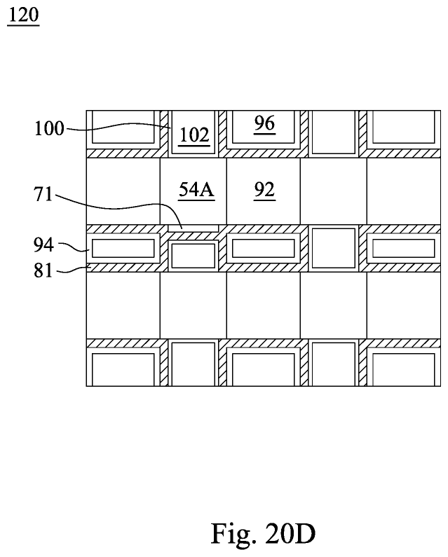

In FIGS. 20A through 20D, source/drain contacts 112 and gate contacts 114, which may be also referred to as conductive contacts, are formed in the fourth recesses 108. FIG. 20D illustrates a top-down view of the structure illustrated in FIGS. 20A, 20B, and 20C, including the second nanostructure 54A, along the reference cross-sections D-D′. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106. The structures shown in FIGS. 20A through 20C may be referred to as semiconductor device 120.

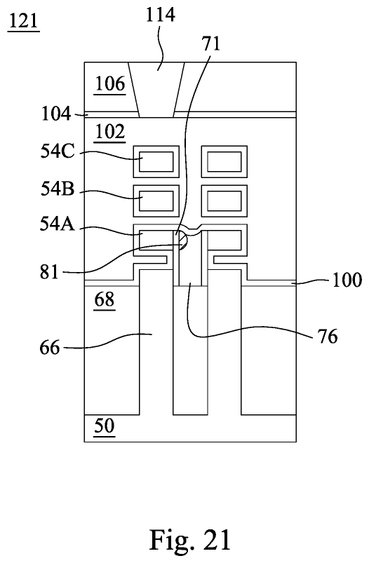

FIG. 21 shows a semiconductor device 121 similar to the semiconductor device 120 shown in FIG. 20A, in accordance with some embodiments, wherein like numerals refer to like features formed by like processes. In the semiconductor device 121, the third portion of the spacers 81 may be connected to the remaining portion of the dummy gate 76 on the STI regions 68. One layer of the dummy gate dielectric 71 may be between the second nanostructure 54A and the third portion of the spacers 81 as well as between the fin 66 and the remaining portion of the dummy gate 76. The vertical location, the horizontal location, and the shape of the third portion of the spacers 81 in FIG. 21 are provided as examples. The third portion of the spacers 81 may be anywhere in the in gate electrodes 102 and may have any shape, which is similar to the third portion of the spacers 81 shown in FIG. 20A.

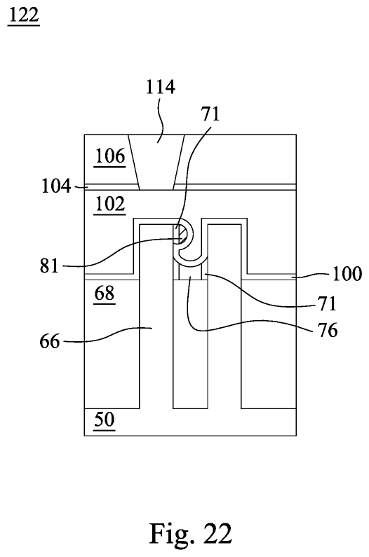

FIG. 22 shows a semiconductor device 122 similar to the semiconductor device 120 shown in FIG. 20A, in accordance with some embodiments, wherein like numerals refer to like features formed by like processes. The semiconductor device 122 may be a fin-FET, wherein top portions of the fins 66 may be channel regions. In the semiconductor device 122, the third portion of the spacers 81 may to be adjacent the top portion of the fin 66 and a portion of the dummy gate dielectrics 71 may between the top portion of the fin 66 and the third portion of the spacers 81.

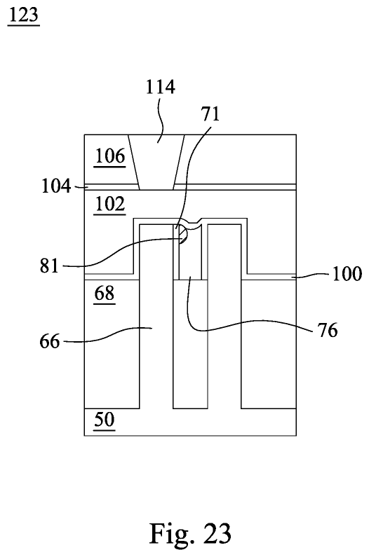

FIG. 23 shows a semiconductor device 123 similar to the semiconductor device 121 shown in FIG. 21, in accordance with some embodiments, wherein like numerals refer to like features formed by like processes. The semiconductor device 123 may be a fin-FET, wherein top portions of the fins 66 may be channel regions. In the semiconductor device 123, the third portion of the spacers 81 may to be adjacent the top portion of the fin 66 and a portion of the dummy gate dielectrics 71 may between the top portion of the fin 66 and the third portion of the spacers 81 as well as between the top portion of the fin 66 and the remaining portion of the dummy gate 76 on the STI regions 68.

FIGS. 24A through 27 are views of intermediate stages in the manufacturing of semiconductor devices, such as nano-FETs, in accordance with some embodiments. FIGS. 24A, 25A, 26A, and 27 illustrate cross-sectional views along the reference cross-section A-A′ illustrated in FIG. 1. FIGS. 24B, 25B, and 26B illustrate cross-sectional views along the reference cross-section B-B′ illustrated in FIG. 1. FIGS. 24C, 25C, and 26C illustrate cross-sectional views along the reference cross-section C-C′ illustrated in FIG. 1.

FIGS. 24A through 24D show similar structures to the ones shown in FIGS. 6A through 6D, in accordance with some embodiments, wherein like numerals refer to like features formed by like processes as described with respect to FIGS. 2 through 6D. FIGS. 24A through 24D illustrate features in either or both the n-type region 50N and/or the p-type region 50P. FIG. 24D illustrates a top-down view of the structure illustrated in FIGS. 24A, 24B, and 24C, including the second nanostructure 54A, along the reference cross-sections D-D′. In the embodiments shown in FIGS. 24A through 24D, the void 73 are encircled by the dummy gate 76 in the cross-sectional view and extend through the dummy gate 76 in the top-down view. The dummy gate 76 may be formed of amorphous silicon or the like. The dummy gate 76 may be formed by a suitable deposition process, such as physical vapor deposition (PVD), CVD, sputter deposition, or the like, and then a patterning process. The deposition temperature may be in range from about 400° C. to about 500° C., and the deposition pressure may be in range from about 0.5 torr to about 2.5 torr. Using amorphous silicon to form the dummy gate 76 may lead to the void 73 being separated from the dummy gate dielectrics 71, which may improve the performance of the subsequently formed semiconductor device.

FIG. 24A shows one void 73 disposed in the dummy gate 76 for illustrative purposes. The dummy gate 76 may have more than one void 73. FIG. 24A shows the vertical location of the void 73 to be adjacent the second nanostructure 54A for illustrative purposes. The vertical location of the void 73 may be anywhere in the dummy gate 76, including the being adjacent other nanostructures in the nanostructures 55 and/or top portions of the fins 66. FIG. 24A shows the horizontal location of the void 73 to be between the two stacks of the nanostructures 55 for illustrative purposes. The horizontal location of the void 73 may be anywhere in the dummy gate layer 72 including being to the left and/or right of the two stacks of the nanostructures 55. FIG. 24A shows the void 73 having a shape of an oval for illustrative purposes. The void 73 may have any shape (e.g., circle).

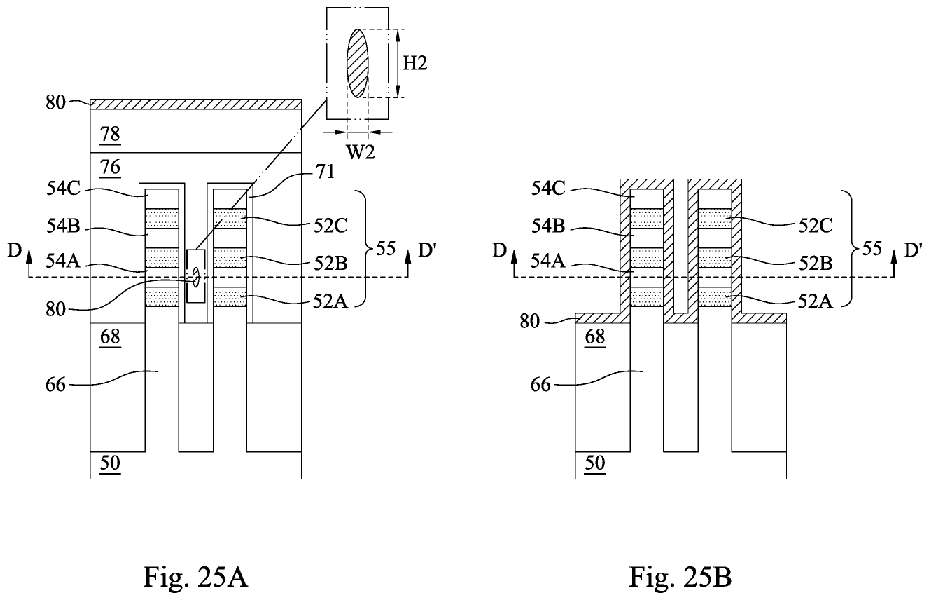

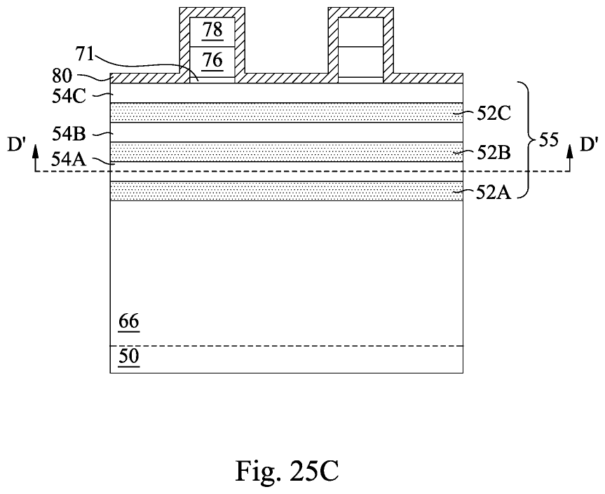

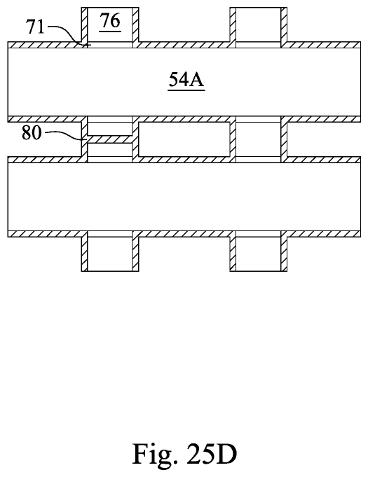

FIGS. 25A through 25D show similar structures to the ones shown in FIGS. 7A through 7D, in accordance with some embodiments, wherein like numerals refer to like features formed by like processes as described with respect to FIGS. 7A through 7D. FIG. 25D illustrates a top-down view of the structure illustrated in FIGS. 25A, 25B, and 25C, including the second nanostructure 54A, along the reference cross-sections D-D′. The spacer layer 80 may at least partially fill the void 73 in the dummy gates 76. As shown in FIG. 25D, a first portion and a second portion of the spacer layer 80 may extend on opposing sides of the dummy gate 76, and a third portion of the spacer layer 80 may extend through the dummy gate 76 and connect to the first portion and the second portion of the spacer layer 80. The first portion, the second portion, and the third portion of the spacer layer 80 may form a shape of an “H” in the top-down view. As shown in FIG. 25A, in some embodiments, the third portion of the spacer layer 80, which fills in the void 73, may be in the shape of an oval with a height H2 in a range from about 1 nm to about 30 nm and a width W2 in a range from about 1 nm to about 30 nm.

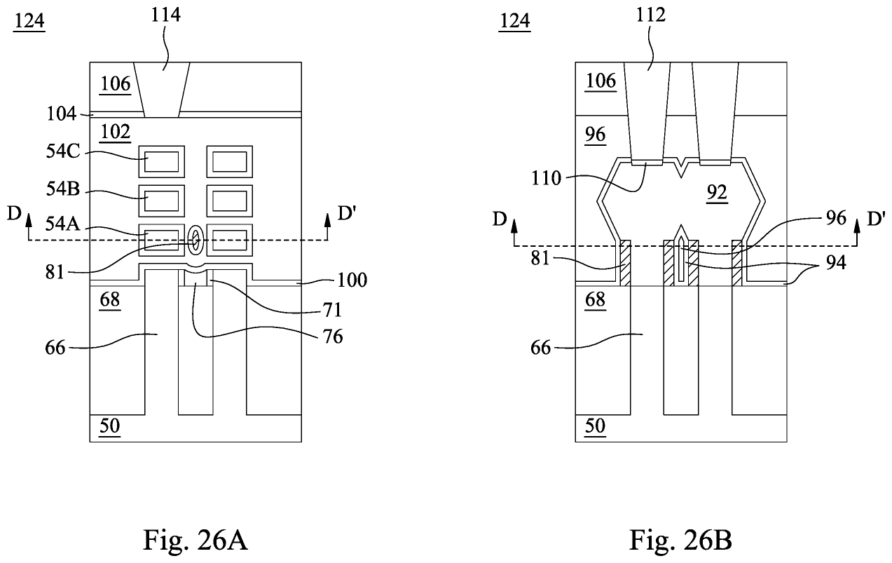

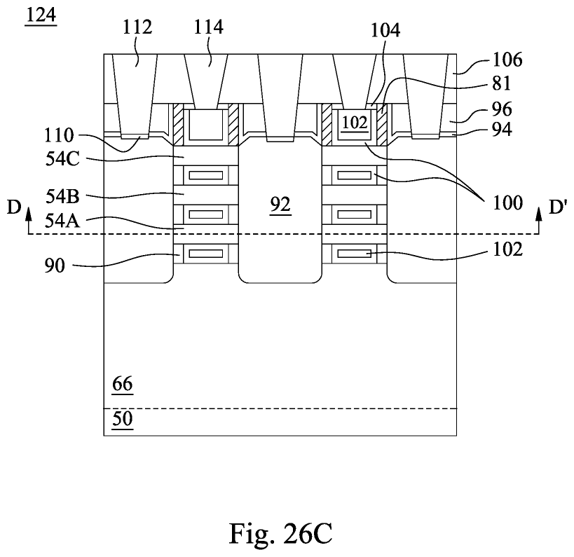

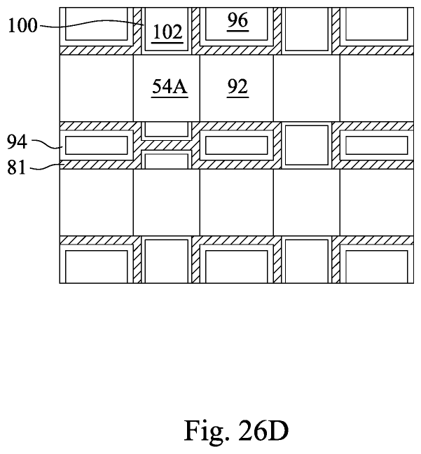

FIGS. 26A through 26D show similar structures to the ones shown in FIGS. 20A through 20D, in accordance with some embodiments, wherein like numerals refer to like features formed by like processes as described with respect to FIGS. 8A through 20D. FIG. 26D illustrates a top-down view of the structure illustrated in FIGS. 26A, 26B, and 26C, including the second nanostructure 54A, along the reference cross-sections D-D′. The structures shown in FIGS. 26A through 26C may be referred to as semiconductor device 124. The gate dielectric layers 100 may be formed on exposed surfaces of the third portion of the spacers 81, and on exposed surfaces of remaining portions of the dummy gate dielectrics 71 and the dummy gates 76. The gate dielectric layers 100 and the gate electrodes 102 may wrap around (e.g., encircle) all of the second nanostructures 54 and the third portion of the spacers 81. The gate dielectric layers 100 and the gate electrodes 102 may extend between the second nanostructures 54 and the third portion of the spacers 81 as well as between the second nanostructures 54 and the fins 66. As a result, an improved control of the channel regions (e.g., the second nanostructures 54) by the gate electrodes 102 may be achieved, thereby improving the performance of the semiconductor device 124. In some embodiments, the gate dielectric layers 100 and the gate electrodes 102 extend between the third portion of the spacers 81 and the remaining portion of the dummy gates 76.

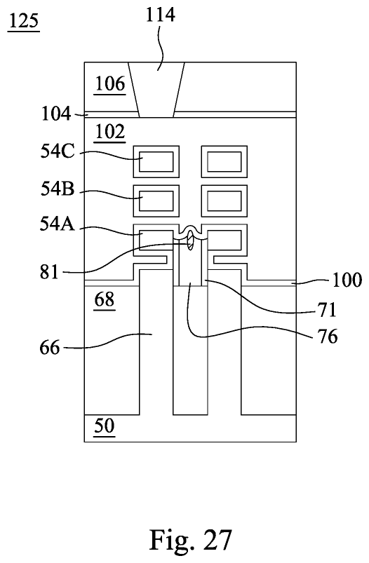

FIG. 27 shows a semiconductor device 125 similar to the semiconductor device 124 shown in FIG. 26A, in accordance with some embodiments, wherein like numerals refer to like features formed by like processes. In the semiconductor device 125, the third portion of the spacers 81 may be connected to the remaining portion of the dummy gate 76 on the STI regions 68. The vertical location, the horizontal location, and the shape of the third portion of the spacers 81 in FIG. 27 are provided as examples. The third portion of the spacers 81 may be anywhere in the in the gate electrodes 102 and may have any shape, which is similar to the third portion of the spacers 81 shown in FIG. 26A.

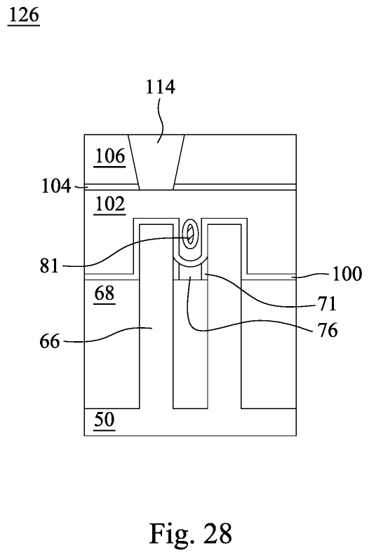

FIG. 28 shows a semiconductor device 126 similar to the semiconductor device 124 shown in FIG. 26A, in accordance with some embodiments, wherein like numerals refer to like features formed by like processes. The semiconductor device 126 may be a fin-FET, wherein top portions of the fins 66 may be channel regions. In the semiconductor device 126, the third portion of the spacers 81 may to be adjacent the top portions of the fins 66.

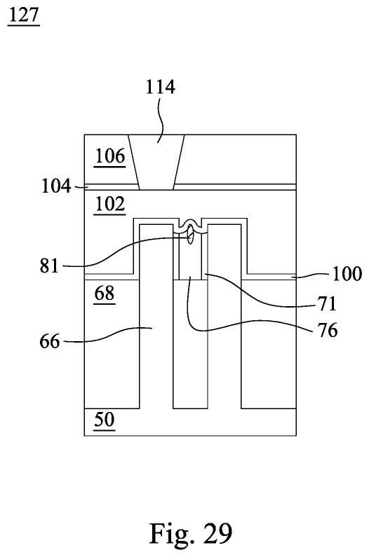

FIG. 29 shows a semiconductor device 127 similar to the semiconductor device 125 shown in FIG. 27, in accordance with some embodiments, wherein like numerals refer to like features formed by like processes. The semiconductor device 127 may be a fin-FET, wherein top portions of the fins 66 may be channel regions. In the semiconductor device 127, the third portion of the spacers 81 may to be adjacent the top portions of the fins 66.

The embodiments of the present disclosure have some advantageous features. By selecting an appropriate material to form the dummy gates 76, an improved control of the channel regions (e.g., the second nanostructures 54) by the gate electrodes 102 may be achieved, thereby improving the performance of various semiconductor devices.

In an embodiment, a semiconductor device includes a substrate; a first channel region and second channel region over the substrate; a gate structure, wherein the gate structure is on one or more sidewalls of the first channel region and on one or more sidewalls of the second channel region; and a dielectric spacer on a first side and a second side of the gate structure in a top-down view, wherein the first side opposes the second side, and wherein a first portion of the dielectric spacer extends between the first channel region and the second channel region. In an embodiment, the semiconductor device further includes a first dielectric layer on a first sidewall of the first channel region, wherein the first portion of the dielectric spacer is on the first dielectric layer, wherein the gate structure is on a second sidewall of the first channel region, and wherein the first sidewall opposes the second sidewall. In an embodiment, the gate structure wraps around the first portion of the dielectric spacer. In an embodiment, the gate structure wraps around the first channel region and the second channel region. In an embodiment, the first channel region and the second channel region are top portions of fin structures protruding from the substrate. In an embodiment, the semiconductor device further comprises a semiconductor dummy gate structure, wherein the first portion of the dielectric spacer is in contact with the semiconductor dummy gate structure. In an embodiment, the semiconductor dummy gate structure comprises amorphous silicon. In an embodiment, the semiconductor device further includes a source/drain region in contact with the first channel region, wherein a second portion of the dielectric spacer extends on a lower sidewall of the source/drain region.

In an embodiment, a semiconductor device includes a substrate; a first channel region over the substrate; a gate structure, wherein the gate structure is on a top surface and one or more sidewalls of the first channel region; and an insulating spacer, wherein a first portion of the insulating spacer is on a first side of the gate structure and a second portion of the insulating spacer is on a second side of the gate structure in a top-down view, wherein the first side opposes the second side, wherein a third portion of the insulating spacer extends through the gate structure in the top-down view, and wherein the third portion of the insulating spacer is in contact with the first portion and the second portion of the insulating spacer. In an embodiment, the first portion, the second portion, and the third portion of the insulating spacer form a shape of an “H” in the top-down view. In an embodiment, the semiconductor device further includes a fin structure protruding from the substrate, wherein the first channel region is over the fin structure, and wherein the gate structure extends between the fin structure and the first channel region. In an embodiment, the gate structure extends between the first channel region and the third portion of the insulating spacer. In an embodiment, the semiconductor device further includes a semiconductor dummy structure underneath the third portion of the insulating spacer, wherein the semiconductor dummy structure comprises amorphous silicon. In an embodiment, the third portion of the insulating spacer extends along a sidewall of the first channel region, and wherein the third portion of the insulating spacer and the first channel region extend through a same opening in the gate structure. In an embodiment, the semiconductor device further includes a semiconductor dummy structure underneath the third portion of the insulating spacer, wherein the semiconductor dummy structure comprises polycrystalline silicon.

In an embodiment, a method of forming a semiconductor device includes forming a first channel region and a second channel region over a substrate; forming a dummy gate structure along a first sidewall of the first channel region and a first sidewall of the second channel region, wherein a void extends through the dummy gate structure; forming a dielectric spacer, wherein a first portion of the dielectric spacer at least partially fills in the void; removing at least a part of the dummy gate structure; and forming a gate structure along the first sidewall of the first channel region and the first sidewall of the second channel region, wherein the first portion of the dielectric spacer extends through the gate structure. In an embodiment, the first portion of the dielectric spacer is between the first channel region and the second channel region. In an embodiment, the gate structure encircles the first portion of the dielectric spacer. In an embodiment, a portion of the dummy gate structure extends between the first channel region and the first portion of the dielectric spacer. In an embodiment, after removing at least a part of the dummy gate structure, a portion of the dummy gate structure remains underneath the first portion of the dielectric spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a first channel region and a second channel region over the substrate;
a gate structure, wherein the gate structure is on one or more sidewalls of the first channel region and on one or more sidewalls of the second channel region; and
a dielectric spacer on a first side and a second side of the gate structure in a top-down view, wherein the first side opposes the second side, and wherein a first portion of the dielectric spacer extends between the first channel region and the second channel region.

2. The semiconductor device of claim 1, further comprising a first dielectric layer on a first sidewall of the first channel region, wherein the first portion of the dielectric spacer is on the first dielectric layer, wherein the gate structure is on a second sidewall of the first channel region, and wherein the first sidewall opposes the second sidewall.

3. The semiconductor device of claim 1, wherein the gate structure wraps around the first portion of the dielectric spacer.

4. The semiconductor device of claim 3, wherein the gate structure wraps around the first channel region and the second channel region.

5. The semiconductor device of claim 3, wherein the first channel region and the second channel region are top portions of fin structures protruding from the substrate.

6. The semiconductor device of claim 1, further comprising a semiconductor dummy gate structure, wherein the first portion of the dielectric spacer is in contact with the semiconductor dummy gate structure.

7. The semiconductor device of claim 6, wherein the semiconductor dummy gate structure comprises amorphous silicon.

8. The semiconductor device of claim 1, further comprising a source/drain region in contact with the first channel region, wherein a second portion of the dielectric spacer extends on a lower sidewall of the source/drain region.

9. A semiconductor device comprising:
a substrate;
a first channel region over the substrate;
a gate structure, wherein the gate structure is on a top surface and one or more sidewalls of the first channel region; and
an insulating spacer, wherein a first portion of the insulating spacer is on a first side of the gate structure and a second portion of the insulating spacer is on a second side of the gate structure in a top-down view, wherein the first side opposes the second side, wherein a third portion of the insulating spacer extends through the gate structure in the top-down view, and wherein the third portion of the insulating spacer is in contact with the first portion and the second portion of the insulating spacer.

10. The semiconductor device of claim 9, wherein the first portion, the second portion, and the third portion of the insulating spacer form a shape of an “H” in the top-down view.

11. The semiconductor device of claim 9, further comprising a fin structure protruding from the substrate, wherein the first channel region is over the fin structure, and wherein the gate structure extends between the fin structure and the first channel region.

12. The semiconductor device of claim 9, wherein the gate structure extends between the first channel region and the third portion of the insulating spacer.

13. The semiconductor device of claim 12, further comprising a semiconductor dummy structure underneath the third portion of the insulating spacer, wherein the semiconductor dummy structure comprises amorphous silicon.

14. The semiconductor device of claim 9, wherein the third portion of the insulating spacer extends along a sidewall of the first channel region, and wherein the third portion of the insulating spacer and the first channel region extend through a same opening in the gate structure.

15. The semiconductor device of claim 14, further comprising a semiconductor dummy structure underneath the third portion of the insulating spacer, wherein the semiconductor dummy structure comprises polycrystalline silicon.

16. A method of forming a semiconductor device, the method comprising:
forming a first channel region and a second channel region over a substrate;
forming a dummy gate structure along a first sidewall of the first channel region and a first sidewall of the second channel region, wherein a void extends through the dummy gate structure;
forming a dielectric spacer, wherein a first portion of the dielectric spacer at least partially fills in the void;
removing at least a part of the dummy gate structure; and
forming a gate structure along the first sidewall of the first channel region and the first sidewall of the second channel region, wherein the first portion of the dielectric spacer extends through the gate structure.

17. The method of claim 16, wherein the first portion of the dielectric spacer is between the first channel region and the second channel region.

18. The method of claim 16, wherein the gate structure encircles the first portion of the dielectric spacer.

19. The method of claim 16, wherein a portion of the dummy gate structure extends between the first channel region and the first portion of the dielectric spacer.

20. The method of claim 16, wherein after removing at least a part of the dummy gate structure, a portion of the dummy gate structure remains underneath the first portion of the dielectric spacer.
